(19) United States
(12) Patent Application Publication
(10) Pub. No.: US 2015/0249054 A1
(43) Pub. Date: Sep. 3, 2015

(54) SUBSTRATE ALIGNMENT MARK AND FABRICATING METHOD THEREOF, AND SUBSTRATE

(71) Applicants: BOE TECHNOLOGY GROUP CO., LTD., Beijing (CN); BEIJING BOE DISPLAY TECHNOLOGY CO., LTD., Beijing (CN)

(72) Inventors: Chuan Tian, Beijing (CN); Zhaohui Hao, Beijing (CN)

(21) Appl. No.: 14/358,074

(22) PCT Filed: Jun. 27, 2013
(86) PCT No.: PCT/CN13/78091

§ 371 Date: May 14, 2014

(30) Foreign Application Priority Data
Mar. 8, 2013 (CN) 201310075174.X

(51) Int. Cl. H01L 23/544; H01L 21/64

(52) U.S. Cl. CPC H01L 23/544; H01L 21/64; H01L 2223/54426

(57) ABSTRACT

A substrate alignment mark and a fabricating method thereof, and a substrate are provided. The substrate alignment mark includes a first alignment mark pattern and a second alignment mark pattern that are formed in a different-layer structure on a substrate, the first alignment mark pattern and the second alignment mark pattern are provided with centers thereof aligned and without overlapping portions. Therefore, because two alignment marks are formed in a different-layer structure on a substrate, when uneven film formation occurs in the process of forming one of the alignment marks, causing the alignment mark to be unidentifiable in alignment, the alignment can still be performed by identifying the other alignment mark, thus identification success rate of alignment marks is increased, and then defective rate caused by failure to identify alignment marks in manufacturing process of the substrate is noticeably decreased.

### TECHNICAL FIELD

Embodiments of the present invention relate to an alignment technical field, and particularly relate to a substrate alignment mark and a fabricating method thereof, and a substrate.

### BACKGROUND

Up to now, liquid crystal display technology has become well-established, and the major competition among various panel companies increasingly focuses on increase in yield rate and reduction in costs. Photolithography is a necessary process in manufacturing a thin film transistor liquid crystal display (“TFT-LCD”); when an exposure machine performs an exposure process, in order to achieve satisfactory alignment between patterns in respective layers, alignment marks are usually fabricated in a peripheral region of a substrate to ensure alignment precision.

Alignment marks of the conventional technology are usually fabricated in a same layer as a gate electrode or a source/drain electrode of a thin film transistor (“TFT”); during a production process, in a plating, depositing, or sputtering process or the like for forming a gate electrode metal layer thin film or a source/drain electrode metal layer thin film, uneven metal film formation may occur, making the alignment marks under a microscope appear to be small black dots in alignment and unable to be identified effectively, and then alignment is not achieved, thus leading to increase in defective rate.

### SUMMARY

In order to solve the above-mentioned technical problem, an embodiment of the present invention provides a substrate alignment mark; the substrate alignment mark comprises a first alignment mark pattern and a second alignment mark pattern that are formed in a different-layer structure on a substrate; the first alignment mark pattern and the second alignment mark pattern are provided with centers thereof aligned and without overlapping portions therebetween.

As for the above-mentioned substrate alignment mark, in an example, the second alignment mark pattern is located in a region enclosed by the first alignment mark pattern; both the first alignment mark pattern and the second alignment mark pattern are of hollow structures, or the first alignment mark pattern is of a hollow structure and the second alignment mark pattern is of a solid structure.

As for the above-mentioned substrate alignment mark, in an example, the first alignment mark pattern and the second alignment mark pattern are of similar structures.

As for the above-mentioned substrate alignment mark, in an example, both the first alignment mark pattern and the second alignment mark pattern are of hollow cross-type structures, or the first alignment mark pattern is of a hollow cross-type structure and the second alignment mark pattern is of a solid cross-type structure.

As for the above-mentioned substrate alignment mark, in an example, the first alignment mark pattern and the second alignment mark pattern are of different structures.

As for the above-mentioned substrate alignment mark, in an example, the first alignment mark pattern is of a hollow cross-type structure and the second alignment mark pattern is of a ring structure, or the first alignment mark pattern is of a hollow cross-type structure and the second alignment mark pattern is of a solid circle structure.

In addition, an embodiment of the present invention further provides a substrate, the substrate is provided with an alignment mark thereon, and the alignment mark comprises any of the above-mentioned substrate alignment marks.

As for the above-mentioned substrate, in an example, a thin film transistor is formed on the substrate; the first alignment mark pattern is made from a same metal layer as a gate electrode of the thin film transistor; the second alignment mark pattern is made from a same metal layer as a source/drain electrode of the thin film transistor.

Accordingly, an embodiment of the present invention further provides a fabricating method of a substrate alignment mark, comprising a step of forming a first alignment mark pattern and a step of forming a second alignment mark pattern; the first alignment mark pattern and the second alignment mark pattern are formed in a different-layer structure on a substrate, and provided with centers thereof aligned and without overlapping portions therebetween.

As for the above-mentioned fabricating method of a substrate alignment mark, in an example, the fabricating method further comprises a step of forming a thin film transistor, the step of forming the first alignment mark pattern comprises forming the first alignment mark pattern in a same layer as a gate electrode of the thin film transistor; the step of forming the second alignment mark pattern comprises forming the second alignment mark pattern in a same layer as a source/drain electrode of the thin film transistor.

### BRIEF DESCRIPTION OF THE DRAWINGS

FIG. 1 is a view illustrating a structure of a substrate alignment mark in the first embodiment of the present invention.

FIG. 2 is a cross-sectional view of FIG. 1 taken along A-A direction.

FIG. 3 is a view illustrating a structure of a substrate alignment mark in the second embodiment of the present invention.

FIG. 4 is a view illustrating a structure of a substrate alignment mark in the third embodiment of the present invention.

FIG. 5 is a view illustrating a structure of a substrate alignment mark in the third embodiment of the present invention.

### DETAILED DESCRIPTION

With reference to accompanying drawings and embodiments, specific implementation of the present invention will be described in detail in the following. The following embodiments are used to describe the present invention and not limitative to the scope of the present invention.

It is to be noticed that the following terms “first,” “second,” “third,” are only used to describe the present invention, and does not indicate relative importance.

### First Embodiment

In order to increase identification success rate of alignment marks during a substrate manufacturing process, this embodiment provides a fabricating method of a substrate alignment mark, the method comprising a step of forming a first alignment mark pattern and a step of forming a second alignment mark pattern. The first alignment mark pattern and the second alignment mark pattern are formed in a different-layer structure on a substrate (here the different-layer structure refers to patterns formed by thin films in different layers on the substrate, and correspondingly, a same-layer structure refers to patterns formed by a thin film in the same layer on the substrate), and are provided with centers thereof aligned with each other, namely, the centers of the first alignment mark pattern and the second alignment mark pattern coincide with each other from top to bottom, and located in a line, so that when alignment is performed with the two alignment marks respectively, alignment uniformity can be maintained. The first alignment mark pattern and the second alignment mark pattern are provided without overlapping portions, to guarantee that, when one of the alignment marks cannot be identified, alignment process is not affected by identifying the other alignment mark.

By fabricating two alignment marks with thin films in different layers on a substrate, the chance that the two layers forming the alignment marks are suffered from uneven film formation simultaneously is very low, so when uneven film formation occurs in the process of forming one of the alignment marks, causing the alignment mark to be unidentifiable in alignment, the alignment can be performed by identifying the other alignment mark, thus increasing identification success rate of the alignment marks.

According to the above embodiment, it is very easy for a person skilled in the art to perceive that more pairs of alignment mark patterns can be fabricated and provided with centers thereof aligned, and any two of the alignment mark patterns are formed in a different-layer structure on the substrate, and the work principle thereof is the same as that of the case where two alignment mark patterns are provided, leading to higher an identification success rate of alignment marks; but the increase in the success rate is limited while fabricating costs will be added, so in general, it is still satisfactory to fabricate two alignment mark patterns only.

With reference to an example of a manufacturing process of an array substrate comprising a bottom-gate-structure TFT, the fabricating process of the substrate alignment mark in this embodiment of the present invention will be described in the following.

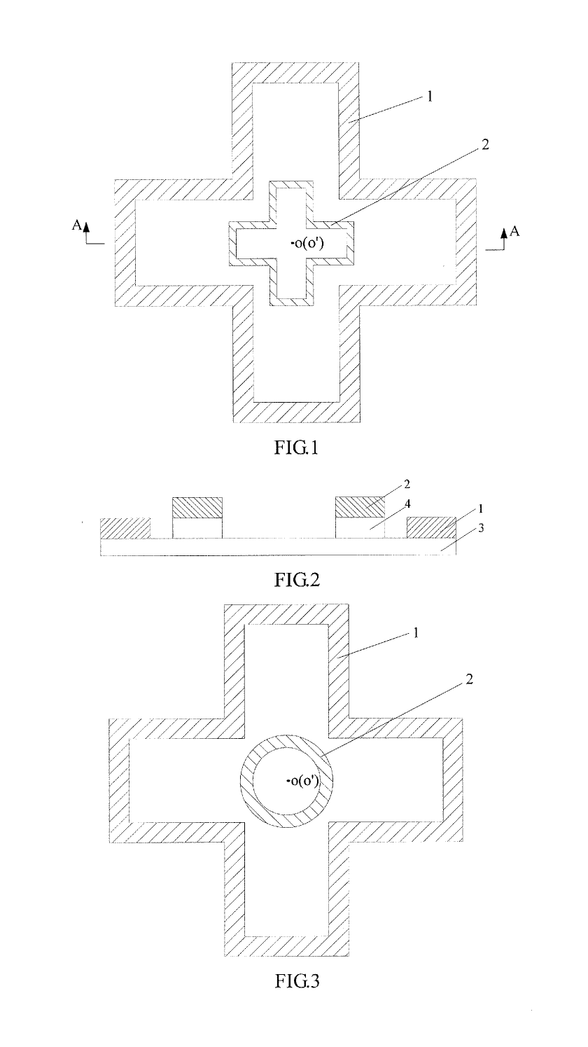

Firstly, a first alignment mark pattern is formed in a same layer as a gate electrode of a transistor thin film. For example, after forming a gate electrode metal layer thin film on a base substrate (for example, a glass substrate, quartz substrate or transparent resin substrate, as illustrated by reference sign 3 in FIG. 2) by plating, depositing, sputtering process or the like, a common mask can be used to form patterns including a TFT gate electrode and the first alignment mark (as illustrated by label 1 in FIG. 2) simultaneously by one patterning process. Usually, the first alignment mark 1 is located in a peripheral region of the base substrate 3.

Then, a second alignment mark pattern is formed in a same layer as a source/drain electrode of the thin film transistor. For example, a gate insulating layer, an active layer (the two layers are illustrated by reference sign 4 in FIG. 2) and a source/drain metal layer thin film are sequentially formed on the base substrate by plating, depositing, sputtering process or the like, and photoresist is coated on the source/drain metal layer thin film; then, for example, a half-tone or gray-tone mask is used to perform an exposing and developing process, so that the photoresist forms a photoresist-partially-retained region, a photoresist-completely-retained region and a photoresist-completely-removed region. The photoresist-partially-retained region corresponds to a channel region of the TFT, the photoresist-completely-retained region corresponds to the TFT source/drain electrode and a region where the second alignment mark is located, and the photoresist-completely-removed region corresponds to a region where the rest patterns are located; then the photoresist on the TFT channel is removed in an ashing process, which functions to reduce the photoresist on the TFT source/drain electrode and the second alignment mark as well; subsequently, the source/drain metal layer thin film on the TFT channel region and part of the active layer (for example, a dry etching method is used to etch the source/drain metal layer thin film on the TFT channel region, and a wet etching method is used to etch part of the active layer in the TFT channel region), to form a TFT channel; finally, the rest photoresist is removed to form patterns of the TFT source/drain electrode and the second alignment mark (as illustrated by reference sign 2 in FIG. 2). Accordingly, the second alignment mark 2 is also located in the peripheral region of the substrate, and the second alignment mark 2 and the first alignment mark 1 are provided with centers thereof located in a line and without overlapping portions.

It is to be noted that, the fabricating method of substrate alignment mark provided by the embodiment of the present invention hereby is only an illustrative example, and suitable for all substrates that need to fabricate an alignment mark, but not limited to an array substrate comprising a bottom-gate-structure TFT. Further, the technical solution that the second alignment mark pattern is formed with a half-tone or gray-tone mask to perform an exposing and developing process is described above, however, as an alternative, it is also suitable to use a common full-tone mask to perform an exposing and developing process so as to form the second alignment mark pattern.

### Second Embodiment

Accordingly, this embodiment provides a substrate alignment mark. As illustrated in FIG. 1-FIG. 5, the substrate alignment mark comprises a first alignment mark pattern 1 and a second alignment mark pattern 2 that are formed in a different-layer structure of a substrate (here the different-layer structure refers to patterns formed by thin films in different layers on a substrate, and correspondingly, a same-layer structures refer to patterns formed by a thin film in a same layer on the substrate); the center o of the first alignment mark pattern 1 and the center o′ of the second alignment mark pattern 2 are aligned with each other, namely, the centers o and o′ of the first alignment mark pattern 1 and the second alignment mark pattern 2 coincide with each other from top to bottom, and are located in a line, so that when alignment is performed with the two alignment marks respectively, alignment uniformity can be maintained. The first alignment mark pattern 1 and the second alignment mark pattern 2 are provided without overlapping portions, to guarantee that, when one of the alignment marks cannot be identified, alignment process is not affected by identifying the other alignment mark.

In order to achieve that the first alignment mark pattern 1 and the second alignment mark pattern 2 are provided without overlapping portions, in this embodiment, the second alignment mark pattern 2 can be designed to be located within a region which is enclosed by the first alignment mark pattern, and the first alignment mark pattern 1 is of a hollow structure, then the second alignment mark pattern 2 can be either of a hollow structure or a solid structure.

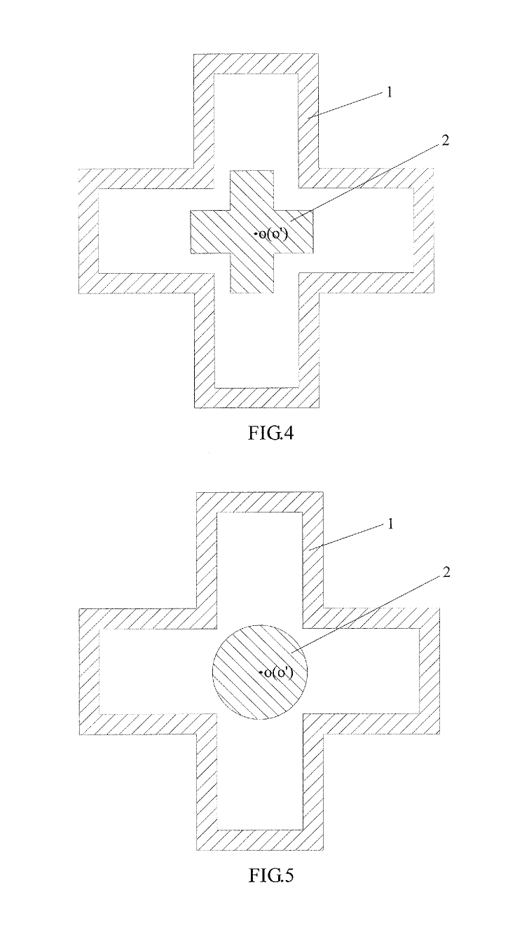

Further, the first alignment mark pattern 1 and the second alignment mark pattern 2 can be of similar structures, namely the first alignment mark pattern 1 and the second alignment mark pattern 2 are the same in profile but different in size only, for example, the first alignment mark pattern 1 is of a hollow cross-type structure and the second alignment mark pattern 2 can be either of a hollow cross-type structure, as illustrated in FIG. 1, or a solid cross-type structure, as illustrated in FIG. 4. Certainly, the first alignment mark pattern 1 and the second alignment mark pattern 2 can also be of different structures, namely, the first alignment mark pattern 1 and the second alignment mark pattern 2 are different in both size and profile, for example, the first alignment mark pattern 1 is of a hollow cross-type structure and the second alignment mark pattern 2 can be either a ring structure, as illustrated in FIG. 3, or a solid circle structure, as illustrated in FIG. 5. It is to be noted that, a cross-type structure, a ring structure and a solid structure are only illustrative examples but not limitative for the structures of the first alignment mark pattern 1 and the second alignment mark pattern 2, and structural combinations of the first alignment mark pattern 1 and the second alignment mark pattern 2 are various.

### Third Embodiment

This embodiment provides a substrate with an alignment mark thereon, and the alignment mark uses the substrate alignment mark in the second embodiment. Because of an increase in identification success rate of alignment marks, defective rate caused by failure to identify alignment marks in manufacturing process of a substrate is noticeably decreased.

With regard to a TFT-LCD array substrate, a thin film transistor is formed on the array substrate; in practice, as illustrated in FIG. 1, the first alignment mark pattern 1 can be designed to be made from a same metal layer as a gate electrode of the thin film transistor, and the second alignment mark pattern 2 is made from a same metal layer as a source/drain electrode of the thin film transistor.

It is can been seen from the above embodiments that, in the substrate alignment mark and the fabricating method thereof provided by the embodiments of the present invention, two alignment mark patterns are formed in a different-layer structure on a substrate, when uneven film formation occurs in the process of forming one of the alignment marks, causing the alignment mark to be unidentifiable in alignment, the alignment can be performed by identifying the other alignment mark, thus identification success rate of alignment marks is increased, and then defective rate caused by failure to identify alignment marks in manufacturing process of the substrate is noticeably decreased.

The embodiments of the present invention provide a substrate alignment mark and a fabricating method thereof, so as to resolve the problem that alignment marks are unidentifiable in alignment due to uneven film formation in the process of fabricating the alignment marks; the embodiments of the present invention further provide a substrate with the above-mentioned substrate alignment mark formed thereon, decreasing the defective rate caused by failure to identify alignment marks in manufacturing process of the substrate.

The above are only part of embodiments of the present invention; it is should be pointed out that, for a common person skilled in the art, modifications and equivalents can further be made without departing from the technical principle of the present invention, and these modifications and equivalents should be within the scope of the present invention.

1. A substrate alignment mark, wherein the substrate alignment mark comprises a first alignment mark pattern and a second alignment mark pattern that are formed in a different-layer structure on a substrate, wherein the first alignment mark pattern and the second alignment mark pattern are provided with centers thereof aligned and without overlapping portions therebetween.

2. The substrate alignment mark as claimed in claim 1, wherein the second alignment mark pattern is located within a region enclosed by the first alignment mark pattern;
both the first alignment mark pattern and the second alignment mark pattern are of hollow structures, or
the first alignment mark pattern is of a hollow structure and the second alignment mark pattern is of a solid structure.

3. The substrate alignment mark as claimed in claim 2, wherein the first alignment mark pattern and the second alignment mark pattern are of similar structures.

4. The substrate alignment mark as claimed in claim 3, wherein both the first alignment mark pattern and the second alignment mark pattern are of hollow cross-type structures, or
the first alignment mark pattern is of a hollow cross-type structure, and the second alignment mark pattern is of a solid cross-type structure.

5. The substrate alignment mark as claimed in claim 2, wherein the first alignment mark pattern and the second alignment mark pattern are of different structures.

6. The substrate alignment mark as claimed in claim 5, wherein the first alignment mark pattern is of a hollow cross-type structure, and the second alignment mark pattern is of a ring structure, or
the first alignment mark pattern is of a hollow cross-type structure, and the second alignment mark pattern is of a solid circle structure.

7. A substrate, comprising an alignment mark thereon, wherein the alignment mark comprises a first alignment mark pattern and a second alignment mark pattern that are formed in a different-layer structure on a substrate, wherein the first alignment mark pattern and the second alignment mark pattern are provided with centers thereof aligned and without overlapping portions therebetween.

8. The substrate as claimed in claim 7, wherein a thin film transistor is formed on the substrate;
the first alignment mark pattern is made from a same metal layer as a gate electrode of the thin film transistor; and the second alignment mark pattern is made from a same metal layer as a source/drain electrode of the thin film transistor.

9. A fabricating method of a substrate alignment mark, comprising a step of forming a first alignment mark pattern and a step of forming a second alignment mark pattern, wherein the first alignment mark pattern and the second alignment mark pattern are formed in a different-layer structure on a substrate, and provided with centers thereof aligned and without overlapping portions therebetween.

10. The fabricating method of a substrate alignment mark as claimed in claim 9, further comprising a step of forming a thin film transistor,
the step of forming the first alignment mark pattern comprising:
forming the first alignment mark pattern in a same layer as a gate electrode of the thin film transistor;
the step of forming the second alignment mark pattern comprising:
forming the second alignment mark pattern in a same layer as a source/drain electrode of the thin film transistor.

11. The substrate as claimed in claim 7, wherein the second alignment mark pattern is located within a region enclosed by the first alignment mark pattern;
both the first alignment mark pattern and the second alignment mark pattern are of hollow structures, or
the first alignment mark pattern is of a hollow structure and the second alignment mark pattern is of a solid structure.

12. The substrate as claimed in claim 11, wherein the first alignment mark pattern and the second alignment mark pattern are of similar structures.

13. The substrate as claimed in claim 12, wherein both the first alignment mark pattern and the second alignment mark pattern are of hollow cross-type structures, or
the first alignment mark pattern is of a hollow cross-type structure, and the second alignment mark pattern is of a solid cross-type structure.

14. The substrate as claimed in claim 11, wherein the first alignment mark pattern and the second alignment mark pattern are of different structures.

15. The substrate as claimed in claim 14, wherein the first alignment mark pattern is of a hollow cross-type structure, and the second alignment mark pattern is of a ring structure, or
the first alignment mark pattern is of a hollow cross-type structure, and the second alignment mark pattern is of a solid circle structure.
